(19) United States
(12) Patent Application Publication
(10) Pub. No.: US 2025/0315077 A1
(43) Pub. Date: Oct. 9, 2025

(54) Synchronization Technique

(71) Applicant: Telefonaktiebolaget LM Ericsson (publ), Stockholm (SE)

(72) Inventors: Balázs Renczes, Budapest (HU); Gábor Kovács, Dunakeszi (HU); Tamás Kovácsházy, Budapest (HU); Balázs Patonai, Budaörs (HU)

(21) Appl. No.: 18/865,512

(22) PCT Filed: May 16, 2022
(86) PCT No.: PCT/EP2022/063212

§ 371 Date: Nov. 13, 2024

(51) Int. Cl. G06F 1/10; G06F 1/12

(52) U.S. Cl. CPC G06F 1/10; G06F 1/12

(57) ABSTRACT

A technique for synchronizing a secondary clock (100; 800; 900; 1091; 1092; 1130) with a primary clock (300) is provided. As to a first method aspect, a method comprises a step of receiving (202), from the primary clock (300), a synchronization signal (302) indicative of a reference time at each of a plurality of synchronization events. The method further comprises a step of estimating (204) an offset and a skew of the secondary clock (100; 800; 900; 1091; 1092; 1130) based on the reference time and a local time retrieved from the secondary clock (100; 800; 900; 1091; 1092; 1130) for each of the synchronization events. The offset and the skew of the secondary clock (100; 800; 900; 1091; 1092; 1130) are estimated (204) using a Kalman filter, KF, comprising an offset variance and a skew variance. The offset variance being indicative of a power of noise of the offset and the skew variance being indicative of a power of noise of the skew. The offset variance is set according to an internal noise power measured for the secondary clock (100; 800; 900; 1091; 1092; 1130). The skew variance is set according to an external influence on the secondary clock (100; 800; 900; 1091; 1092; 1130) measured for an environment of the secondary clock (100; 800; 900; 1091; 1092; 1130). The method further comprises a step of updating (206) the secondary clock (100; 800; 900; 1091; 1092; 1130) based on the estimated (204) offset and skew.

### TECHNICAL FIELD

The present disclosure relates to a technique for synchronizing a clock in network. More specifically, and without limitation, methods and devices are provided for synchronizing a secondary clock with a primary clock, using a Kalman filter.

### BACKGROUND

The Third Generation Partnership Project (3GPP) expanded for Release 17 of the Fifth Generation (5G) system the support for Time Synchronization and Time Sensitive communications for any application. In such telecommunication systems, accurate time synchronization of network elements is a key function to enable advanced radio functions such as ultra-reliable low-latency communication (URLLC) and to maximize capacity of radio networks. Accordingly, the telecommunication systems have an inner clock, and the accuracy and stability of the clock is a key performance indicator. Therefore, a clock recovery process is performed for the clock.

The clock comprises a local oscillator. One challenging situation is when the stability of the local oscillator degrades so that the clock recovery process faces a sudden frequency change. The clock recovery process should be able to detect that such frequency change is coming from the local oscillator and needs to act accordingly. A Kalman filter is a known process used to filter out noises. A linear Kalman filter was introduced by Giorgi and Narduzzi (Giada Giorgi and Claudio Narduzzi, “Performance analysis of Kalman-filter-based clock synchronization in IEEE 1588 networks.” IEEE transactions on instrumentation and measurement 60.8 (2011): 2902-2909) to filter out white and random walk (skew) frequency noises.

The linear Kalman filter controls both frequency fluctuations and actual phase changes of the oscillator. The numerical simulations show that the filtering approach is efficient even on longer synchronization intervals (e.g., 10² s to 10³ s). However, this filter cannot follow sudden changes in frequency such as a steep rate ramp.

The sudden changes in frequency can be suppressed by other methods such as extended Kalman filters. For example an extended Kalman filter (M. Apraiz, R. Diego, J. Barros, “An Extended Kalman Filter Approach for Accurate Instantaneous Dynamic Phasor Estimation,” Energies, 11 (11), 2018) was designed for synchro-phasor measurements. In the area of clock synchronization, a Sage-Husa Kalman filter was adapted to mitigate the effect of a rate ramp (Z. Y. Miao, F. Shen, D. J. Xu, Cm M. Tian, K. P. He, “Online estimation method of Allan variance coefficients for MEMS IMU,” Journal of Instrumentation 9, 2014).

The drawback of both methods is that the corresponding models are non-linear and consequently not fast and robust to use. In case of extended Kalman filters, instability problems may occur if the filter is used outside the vicinity of the operating point. Finally, it is also possible to model the rate ramp as a deterministic process in a linear Kalman filter (C. Marselli, D. Daudet, H. Amann, F. Pellandini, “Application of Kalman filtering to noise reduction on microsensor signals.” Proceedings of the Colloque interdisciplinaire en instrumentation, C21, pp. 443-450, 1998). However, by this means, the flexibility of the model is lost, and the rate ramp is required to be present in the system.

In case of a sudden frequency change in the local oscillator clock signal, a controller (e.g., a servo) needs to react quickly to compensate for the drift of the local clock and prevent the drift of the recovered time. Existing linear Kalman-filter solutions are not able to handle such deterministic drift of the local oscillators. In sum of the above, there are two known alternatives and two extension to the linear Kalman-filter to handle such situation:
By using extended Kalman-filters, the rate ramp can be handled. However, extended Kalman filters may have instability problems if not used in their intended operating point.
By using Sage-Husa Kalman filters, the rate ramp is determined in an adaptive manner. Therefore, response time to sudden frequency changes can be too long.
Linear Kalman filters can be extended with state machines, which detect changing circumstances (i.e., rate ramp), and reconfigure the linear Kalman-filter to accommodate the new situation. However, implementation of such detection can be challenging and lead to sub-optimal solution.
The rate ramp can be modeled with a linear Kalman filter as a deterministic process. However, in this case, it is required to be present in the system all the time.

### SUMMARY

Accordingly, there is a need for a synchronization technique that fulfills robustness and responsiveness requirements in at least some situations.

As to a method aspect, a method of synchronizing a secondary clock with a primary clock, is provided. The method comprises receiving, from the primary clock, a synchronization signal indicative of a reference time at each of a plurality of synchronization events. The method further comprises estimating an offset and a skew of the secondary clock based on the reference time and a local time retrieved from the secondary clock for each of the synchronization events. The offset and the skew of the secondary clock are estimated using a Kalman filter (KF) comprising an offset variance and a skew variance. The offset variance is indicative of a power of noise of the offset. The skew variance is indicative of a power of noise of the skew. The offset variance is set according to an internal noise power measured for the secondary clock. The skew variance is set according to an external influence on the secondary clock measured for an environment of the secondary clock. The method further comprises updating the secondary clock based on the estimated offset and skew.

By setting the offset variance according to the internal noise power and the skew variance according to the external influence, embodiments of the method realize a fast response behavior embedded in the (e.g., linear KF) filter that combines robust filter operation with a fast response to a rate ramp caused by the external influence on the secondary clock measured for the environment of the secondary clock.

Same or further embodiments may achieve a suppression of a rate ramp in clock synchronization (e.g., in clock synchronization protocols) by means of the (e.g., linear) KF.

The power of noise (e.g. the power of noise of the offset or the power of noise of the skew) may be a variance (e.g., a variance of the offset or a variance of the skew).

The skew may be caused by the external influence of the environment on the secondary clock.

The secondary clock may be updated based on an a posteriori estimate of the offset and the skew provided by the KF.

The KF may comprise a covariance matrix. The offset variance and the skew variance may be diagonal elements or eigenvalues of the covariance matrix.

The offset variance may be set to the internal noise power (measured for the secondary clock) multiplied by a periodicity of the synchronization events or may be set to the internal noise energy per synchronization event (e.g., since the last synchronization event).

The noise of the offset may be represented by random walk Gaussian noise or integrated white noise (e.g., according to the offset variance and/or with expectation value zero). Alternatively or in addition, the noise of the skew may be represented by random walk Gaussian noise or white noise (e.g., according to the skew variance and/or with expectation value zero). Herein, white noise may refer to noise that is independent of frequency. The random walk may be understood as a rankom walk noise in offset (e.g., random walk offset noise may be integrated from white frequency noise).

The synchronization signals may be received according to a precision time protocol (PTP).

The steps of estimating and updating may be collectively referred to as controlling the secondary clock by means of the KF. Alternatively or in addition, the updating may stabilize a frequency of the secondary clock to the nominal frequency by applying the estimated skew as a negative correction to the secondary clock. Alternatively or in addition, the updating may eliminate or reduce the offset of the secondary clock by applying the estimated offset as a negative correction to the secondary clock.

The KF may track both the offset and the skew, and the updating of the secondary clock may comprise updating both the offset and the skew, e.g. in order to obtain both frequency synchronization and phase synchronization of the secondary clock with respect to the primary clock.

The dynamics of the skew may also be referred to as a random walk, e.g. since the dynamics of the skew does not comprise a drift. Alternatively or in addition, the dynamics of the offset may comprise a drift that is proportional to the skew.

The offset (e.g., according to the method aspect) may represent a difference between the local time retrieved from the secondary clock and the reference time at the respective synchronization event.

The offset may correspond to

$$θ ( {T}_{n} ) = C ( {T}_{n} ) - {T}_{n} ,$$

wherein the local time C(Tₙ) is retrieved from the secondary clock for the synchronization event at reference time Tₙ.

The skew (e.g., according to the method aspect) may represent a normalized difference between a frequency of the secondary clock and a nominal frequency of the secondary clock at the respective synchronization event.

The difference may be normalized by dividing the difference by the nominal frequency.

The skew may correspond to

$${γ}_{i} = \frac{{f}_{i -} {f}_{0}}{{f}_{0}} ,$$

wherein the frequency of the secondary clock is fᵢ at the synchronization event at reference time Tᵢ, and the nominal frequency f₀. Alternatively or in addition, the nominal frequency may be constant.

The secondary clock (e.g., according to the method aspect) may comprise a local oscillator. Alternatively or in addition, the frequency of the secondary clock may be the frequency of the local oscillator and/or the nominal frequency of the secondary clock may be the nominal frequency of the local oscillator.

A change in the environment may cause the skew of the secondary clock (e.g., according to the method aspect), optionally the skew of the frequency of the local oscillator.

A time or a time difference between the synchronization events (e.g., according to the method aspect) may be less than 1 s or less than 0.5 s.

The synchronization events (e.g., according to the method aspect) may occur periodically.

A periodicity (also referred to as synchronization interval) of the periodic synchronization events may be 31.25 ms to 500 ms or 1000 ms, e.g., 62.5 ms, 125 ms, 250 ms (milliseconds).

The offset variance (e.g., according to the method aspect) may be proportional to the time difference between the synchronization events.

The skew variance may be proportional to the square value of the time difference between the synchronizations.

The skew variance (e.g., according to the method aspect) may be set to the square value of an upper bound of the change in frequency caused by the external influence on the secondary clock during the time between the synchronization events.

The offset variance (e.g., according to the method aspect) may be configured to track the change of the offset during the time between the synchronizations and/or during a time interval in the range of 0.1 seconds to 1 second.

The external influence (e.g., according to the method aspect) may cause, or may be represented by, a linear change of the frequency of the secondary clock as a function of time.

The linear increase of the frequency as a function of time may also be referred to as a rate ramp. The linear increase may last for half a second, or 1 second or up to 2 minutes.

The linear increase may comprise at least one or two or more than 20 synchronization events. Alternatively or in addition, the linear increase may comprise at most one or two or 20 synchronization events.

The skew variance (e.g., according to the method aspect) may be proportional to the square value of a rate of a linear change or the (e.g., above-mentioned) linear change of the frequency.

The rate of the linear change of the frequency as a function of time may also be referred to as a slope of the rate ramp.

The external influence (e.g., according to the method aspect) may be a change in the environment of the secondary clock.

The secondary clock (e.g., according to the method aspect), alternatively or in addition, the local oscillator, may be thermally coupled to a heat sink, optionally a radiator for radiating heat from the local oscillator to the environment. The external influence may comprise at least one of a failure of a heat pump coupling the heat sink and the local oscillator; a failure of a ventilator at the heat sink; an exposure of the heat sink to sunlight depending on solar altitude; an increase in the temperature of the local oscillator, optionally causing an increase in the frequency; and a decrease in the temperature of the local oscillator, optionally causing a decrease in the frequency.

The external influence may change the temperature of the local oscillator, and the frequency of the local oscillator may depend on the temperature. Since the skew tracks the change of the frequency of the local oscillator, by setting the skew variance according to the measured external influence, the external influence can be compensated.

The KF may be a linear KF. Alternatively or in addition, the KF (e.g., according to the method aspect) may not comprise a multi-state machine for detecting the external influence.

The skew variance (e.g., according to the method aspect) may comprise a dimensionless coefficient.

The skew variance (e.g., according to the method aspect) may be increased if a maximum of a measured offset between the local time and the reference time over a measurement interval is greater than a predefined time error limit. The measurement interval may be greater than the time between the synchronization events.

The coefficient may be adjustable according to the expected external influence. For example, the skew variance may be set proportional to the square value of a slope of the rate ramp.

At least some method embodiments may be implemented in a radio network, e.g., a radio access network (RAN) or a core network (CN). For example, the secondary clock may be a local clock at a network node of the RAN or a function of the CN.

Alternatively or in addition, the secondary clock may be a local clock at a radio device configured for radio access to a network node or a RAN. Without limitation, for example in a 3GPP implementation, any radio device may be a user equipment (UE).

The technique may be used for operating a device (e.g., a radio device or a network node) according to 3GPP New Radio (NR) or 3GPP Long Term Evolution (LTE) or the standard family IEEE 802.11 (Wi-Fi). Alternatively or in addition, the technique may be implemented in a radio device operating on a sidelink (SL), e.g. according to 3GPP NR or 3GPP LTE. Any radio device may be a user equipment (UE), e.g., according to a 3GPP specification, optionally a relay radio device forwarding data from and to the RAN, or a remote radio device connected to the RAN through a relay radio device.

The RAN may comprise one or more base stations, e.g., performing the method aspect. Alternatively or in addition, the radio network may be a vehicular, ad hoc and/or mesh network comprising two or more radio devices (e.g., vehicles such as cars), e.g., acting as the remote radio device and/or the relay radio device and/or performing the method aspect.

Any of the radio devices may be a 3GPP user equipment (UE) or a Wi-Fi station (STA). The radio device may be a mobile or portable station, a device for machine-type communication (MTC), a device for narrowband Internet of Things (NB-IoT) or a combination thereof. Examples for the UE and the mobile station include a mobile phone, a tablet computer and a self-driving vehicle. Examples for the portable station include a laptop computer and a television set. Examples for the MTC device or the NB-IoT device include robots, sensors and/or actuators, e.g., in manufacturing, automotive communication and home automation. The MTC device or the NB-IoT device may be implemented in a manufacturing plant, household appliances and consumer electronics.

Whenever referring to the RAN, the RAN may be implemented by one or more base stations.

The base station may encompass any station that is configured to provide radio access to any of the radio devices. The base stations may also be referred to as cell, transmission and reception point (TRP), radio access node or access point (AP). The base station and/or the relay radio device may provide a data link to a host computer providing the user data to the remote radio device or gathering user data from the remote radio device. Examples for the network node (e.g., base station) may include a 3G base station or Node B (NB), 4G base station or eNodeB (eNB), a 5G base station or gNodeB (gNB), a Wi-Fi AP, and a network controller (e.g., according to Bluetooth, ZigBee or Z-Wave).

The RAN may be implemented according to the Global System for Mobile Communications (GSM), the Universal Mobile Telecommunications System (UMTS), 3GPP Long Term Evolution (LTE) and/or 3GPP New Radio (NR).

Any aspect of the technique may be implemented on a Physical Layer (PHY), a Medium Access Control (MAC) layer, a Radio Link Control (RLC) layer, a packet data convergence protocol (PDCP) layer, and/or a Radio Resource Control (RRC) layer of a protocol stack for the radio communication.

Herein, referring to a protocol of a layer may also refer to the corresponding layer in the protocol stack. Vice versa, referring to a layer of the protocol stack may also refer to the corresponding protocol of the layer. Any protocol may be implemented by a corresponding method.

As to another aspect, a computer program product is provided. The computer program product comprises program code portions for performing any one of the steps of the method aspect disclosed herein when the computer program product is executed by one or more computing devices. The computer program product may be stored on a computer-readable recording medium. The computer program product may also be provided for download, e.g., via the radio network, the RAN, the Internet and/or the host computer. Alternatively, or in addition, the method may be encoded in a Field-Programmable Gate Array (FPGA) and/or an Application-Specific Integrated Circuit (ASIC), or the functionality may be provided for download by means of a hardware description language.

As to a device aspect, a device for synchronizing a secondary clock with a primary clock is provided. The device comprising memory operable to store instructions and processing circuitry operable to execute the instructions, such that the device is operable to receive, from the primary clock, a synchronization signal indicative of a reference time at each of a plurality of synchronization events. The device is further operable to estimate an offset and a skew of the secondary clock based on the reference time and a local time retrieved from the secondary clock for each of the synchronization events. The offset and the skew of the secondary clock are estimated using a Kalman filter (KF). The KF comprises an offset variance and a skew variance. The offset variance is indicative of a power of noise of the offset. The skew variance is indicative of a power of noise of the skew. The offset variance is set according to an internal noise power measured for the secondary clock. The skew variance is set according to an external influence on the secondary clock measured for an environment of the secondary clock. The device is further operable to update (e.g., control) the secondary clock based on the estimated offset and skew.

The radio device (e.g., according to the device aspect) may be further operable to perform any of the steps of the method aspect.

As to a further device aspect, a device for synchronizing a secondary clock with a primary clock is provided. The device is configured to receive, from the primary clock, a synchronization signal indicative of a reference time at each of a plurality of synchronization events. The device is further configured to estimate an offset and a skew of the secondary clock based on the reference time and a local time retrieved from the secondary clock for each of the synchronization events. The offset and the skew of the secondary clock are estimated using a Kalman filter (KF) comprising an offset variance and a skew variance, the offset variance being indicative of a power of noise of the offset and the skew variance being indicative of a power of noise of the skew. The offset variance is set according to an internal noise power measured for the secondary clock. The skew variance is set according to an external influence on the secondary clock measured for an environment of the secondary clock. The device is further configured to update the secondary clock based on the estimated offset and skew.

The radio device (e.g., according to the further device aspect) may be further operable to perform any of the steps of the method aspect.

As to a still further device aspect, a user equipment (UE) for synchronizing a secondary clock with a primary clock is provided. The UE is configured to communicate with a base station, or with a radio device functioning as a gateway. The UE comprises a radio interface and processing circuitry configured to receive, from the primary clock, a synchronization signal indicative of a reference time at each of a plurality of synchronization events. The processing circuitry is further configured to estimate an offset and a skew of the secondary clock based on the reference time and a local time retrieved from the secondary clock for each of the synchronization events. The offset and the skew of the secondary clock are estimated using a Kalman filter (KF). The KF comprises an offset variance and a skew variance, the offset variance being indicative of a power of noise of the offset and the skew variance being indicative of a power of noise of the skew. The offset variance is set according to an internal noise power measured for the secondary clock. The skew variance is set according to an external influence on the secondary clock measured for an environment of the secondary clock. The processing circuitry is further configured to update the secondary clock based on the estimated offset and skew.

The UE may be a vehicle, e.g. a drone or a car. Alternatively or in addition, the UE may be a (e.g., home) appliance.

The processing circuitry of the UE (e.g., according to the still further device aspect) may be further configured to execute any one of the steps of the method aspect.

As to a still further device aspect, a network node for synchronizing a secondary clock with a primary clock is provided. The device comprises memory operable to store instructions and processing circuitry operable to execute the instructions, such that the network node is operable to receive, from the primary clock, a synchronization signal indicative of a reference time at each of a plurality of synchronization events. The processing circuitry is further operable to estimate an offset and a skew of the secondary clock based on the reference time and a local time retrieved from the secondary clock for each of the synchronization events.

The offset and the skew of the secondary clock are estimated using a Kalman filter (KF) comprising an offset variance and a skew variance, the offset variance being indicative of a power of noise of the offset and the skew variance being indicative of a power of noise of the skew. The offset variance is set according to an internal noise power measured for the secondary clock and wherein the skew variance is set according to an external influence on the secondary clock measured for an environment of the secondary clock. The processing circuitry is further operable to update the secondary clock based on the estimated offset and skew.

The network node (e.g., according to the device aspect) may be further operable to perform any one of the steps of the method aspect.

As to a device aspect a network node for synchronizing a secondary clock with a primary clock is provided. The network node is configured to receive, from the primary clock, a synchronization signal indicative of a reference time at each of a plurality of synchronization events. The network node is further configured to estimate an offset and a skew of the secondary clock based on the reference time and a local time retrieved from the secondary clock for each of the synchronization events. The offset and the skew of the secondary clock are estimated using a Kalman filter (KF). The KF comprises an offset variance and a skew variance, the offset variance being indicative of a power of noise of the offset and the skew variance being indicative of a power of noise of the skew. The offset variance is set according to an internal noise power measured for the secondary clock, and the skew variance is set according to an external influence on the secondary clock measured for an environment of the secondary clock. The network node is further configured to update the secondary clock based on the estimated offset and skew.

The network node (e.g., according to the still further device aspect) may be further configured to perform any one of the steps of the method aspect.

As to a still further device aspect a base station for synchronizing a secondary clock with a primary clock is provided. The base station is configured to receive, from the primary clock, a synchronization signal indicative of a reference time at each of a plurality of synchronization events. The base station is further configured to estimate an offset and a skew of the secondary clock based on the reference time and a local time retrieved from the secondary clock for each of the synchronization events. The offset and the skew of the secondary clock are estimated using a Kalman filter (KF) comprising an offset variance and a skew variance, the offset variance being indicative of a power of noise of the offset and the skew variance being indicative of a power of noise of the skew. The offset variance is set according to an internal noise power measured for the secondary clock and wherein the skew variance is set according to an external influence on the secondary clock measured for an environment of the secondary clock. The base station is further configured to update the secondary clock based on the estimated offset and skew.

The base station (e.g., according to the device aspect) may be further configured to perform any one of the steps of the method aspect.

As to a still further aspect, a communication system including a host computer is provided. The host computer comprises a processing circuitry configured to provide user data. The host computer further comprises a communication interface configured to forward the user data to a cellular network (e.g., the RAN and/or the base station) for transmission to a UE.

A processing circuitry of the cellular network may be configured to execute any one of the steps of the method aspect. Alternatively or in addition, the UE comprises a radio interface and processing circuitry, which is configured to execute any one of the steps of the method aspect.

The communication system may further include the UE. Alternatively, or in addition, the cellular network may further include one or more base stations configured for radio communication with the UE and/or to provide a data link between the UE and the host computer using the method aspect.

The processing circuitry of the host computer may be configured to execute a host application, thereby providing the user data and/or any host computer functionality described herein. Alternatively, or in addition, the processing circuitry of the UE may be configured to execute a client application associated with the host application.

Any one of the devices, the UE, the base station, the communication system or any node or station for embodying the technique may further include any feature disclosed in the context of the method aspect, and vice versa. Particularly, any one of the units and modules disclosed herein may be configured to perform or initiate one or more of the steps of the method aspect.

### BRIEF DESCRIPTION OF THE DRAWINGS

Further details of embodiments of the technique are described with reference to the enclosed drawings, wherein:

FIG. 1 shows a schematic block diagram of an embodiment of a device for synchronizing a secondary clock with a primary clock or an embodiment of a secondary clock for performing a synchronization;

FIG. 2 shows a flowchart for a method of synchronizing a secondary clock with a primary clock;

FIGS. 3a and 3b schematically illustrate systems comprising an example of a primary clock and an embodiment of a secondary clock performing a method of synchronization with a primary clock;

FIGS. 4a and 4b show an example of a sudden change in frequency and a result of filtering out the sudden change in a secondary clock according to the prior art;

FIGS. 5a and 5b show an example of a sudden change in frequency and a result of filtering out the sudden change in a secondary clock according to the prior art;

FIGS. 6a and 6b show an example of a sudden change in frequency and a result of filtering out the sudden change in a secondary clock according to the method of FIG. 2;

FIG. 7 schematically illustrates a 5G system as an example of time-aware or time-sensitive system;

FIG. 8 shows a schematic block diagram of a radio device embodying the device of FIG. 1;

FIG. 9 shows a schematic block diagram of a network node embodying the device of FIG. 1;

FIG. 10 schematically illustrates an example telecommunication network connected via an intermediate network to a host computer;

FIG. 11 shows a generalized block diagram of a host computer communicating via a base station or radio device functioning as a gateway with a piece of user equipment over a partially wireless connection; and

FIGS. 12 and 13 show flowcharts for methods implemented in a communication system including a host computer, a base station or radio device functioning as a gateway and a piece of user equipment.

### DETAILED DESCRIPTION

In the following description, for purposes of explanation and not limitation, specific details are set forth, such as a specific network environment in order to provide a thorough understanding of the technique disclosed herein. It will be apparent to one skilled in the art that the technique may be practiced in other embodiments that depart from these specific details. Moreover, while the following embodiments are primarily described for a New Radio (NR) or 5G implementation, it is readily apparent that the technique described herein may also be implemented for any other radio communication technique, including a Wireless Local Area Network (WLAN) implementation according to the standard family IEEE 802.11, 3GPP LTE (e.g., LTE-Advanced or a related radio access technique such as MulteFire), for Bluetooth according to the Bluetooth Special Interest Group (SIG), particularly Bluetooth Low Energy, Bluetooth Mesh Networking and Bluetooth broadcasting, for Z-Wave according to the Z-Wave Alliance or for ZigBee based on IEEE 802.15.4.

Moreover, those skilled in the art will appreciate that the functions, steps, units and modules explained herein may be implemented using software functioning in conjunction with a programmed microprocessor, an Application Specific Integrated Circuit (ASIC), a Field Programmable Gate Array (FPGA), a Digital Signal Processor (DSP) or a general purpose computer, e.g., including an Advanced RISC Machine (ARM). It will also be appreciated that, while the following embodiments are primarily described in context with methods and devices, the invention may also be embodied in a computer program product as well as in a system comprising at least one computer processor and memory coupled to the at least one processor, wherein the memory is encoded with one or more programs that may perform the functions and steps or implement the units and modules disclosed herein.

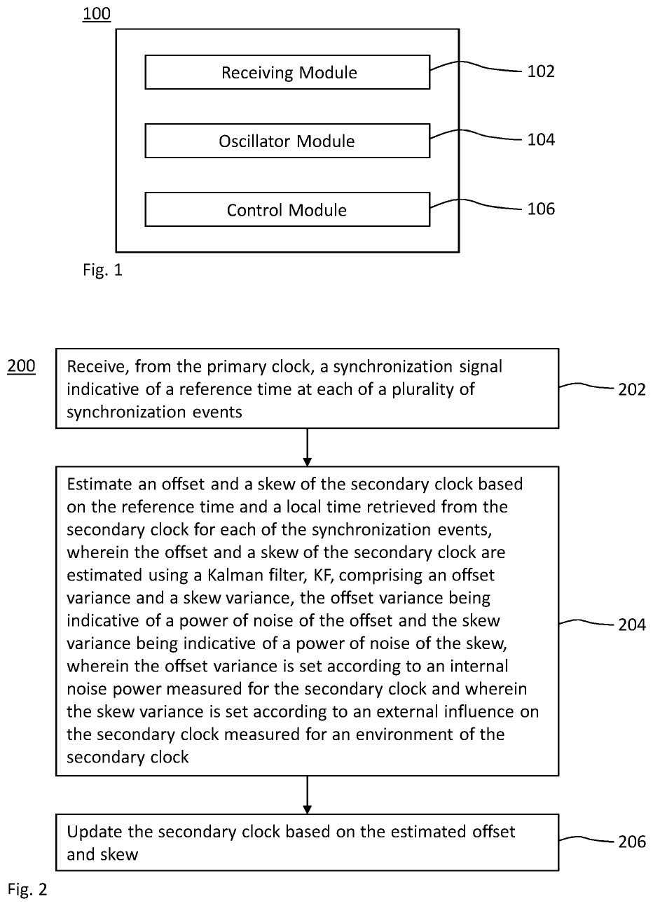

FIG. 1 schematically illustrates a block diagram of an embodiment of a device for applying a synchronization method 200. The device is generically referred to by reference sign 100. The device 100 may be referred to as a secondary clock 100.

The device 100 may also be referred to as slave clock 100 and/or replica clock 100, or may be embodied by, the secondary clock 100. The secondary clock 100 and the primary clock (e.g., a master clock and/or a grand master clock) may be in direct radio communication, e.g., at least for the receiving of the synchronization signal from the primary clock at the secondary clock 100. The primary clock may be embodied by a device 300.

The secondary clock 100 comprises a receiving module 102 that is able to receive a synchronization signal from another device (e.g., primary clock and/or master clock and/or grand master clock). The synchronization signal may be indicative of a reference time at each of a plurality of synchronization events.

In any embodiment, the primary and/or secondary clock may be, or may comprise, a device that counts events indicating the passage of a predefined time interval (e.g., 1 second), and uniquely labels each of these intervals (for example, Jan. 10, 1974, 10:14:03 AM). The events (e.g., synchronization events) are generated by a frequency standard, based on the observation of a physical process (such as the vibration of a quartz crystal or the caesium standard, i.e., the photon absorption by transitions between the two hyperfine ground states of caesium-133 atoms).

The secondary clock 100 further comprises an oscillator module 104 (e.g., local oscillator 104). The local oscillator 104 may be a crystal oscillator (e.g., quartz crystal oscillator or any other type of oscillator). The secondary clock 100 (e.g., the crystal oscillator that is used in a standard clock oscillator) may have applications in many areas of the electronics and telecommunications industry. The local oscillator 104 is used to establish a local (reference) frequency used for timing purposes.

The frequency generated by the local oscillator 104 (e.g., a quartz oscillator) may be affected by a number of environmental factors (e.g., external influences) such as the voltage applied to it, the ambient temperature, acceleration in space (e.g., shock or attitude changes), magnetic fields, and so forth.

The secondary clock 100 and/or the local oscillator 104 may be thermally coupled to a heat sink (e.g., a radiator for radiating heat from the local oscillator 104 to the environment). The external influence comprises at least one of:
a failure of a heat pump coupling the heat sink and the local oscillator 104;
a failure of a ventilator at the heat sink;
an exposure of the heat sink to sunlight depending on solar altitude;
an increase in the temperature of the local oscillator 104, optionally causing an increase in the frequency; and
a decrease in the temperature of the local oscillator 104, optionally causing a decrease in the frequency.

The external influence may change the temperature of the local oscillator 104 and consequently the frequency of the local oscillator.

The quality of the secondary clock 100 is mainly related to its frequency stability—that is, the ability of its frequency standard to provide (e.g., emit) events at a constant frequency over time. The absolute value of the frequency compared to the desired value—or, its frequency accuracy—is also important. Normally a calibration (e.g., a method for compensation and filtering) can compensate to some extent for a stable standard.

The most common frequency stabilities are 25, 50 and 100 part per billion (PPB or ppb). Overall frequency stability usually includes accuracy at 25° C., effects due to changes in operating temperature, input voltage, aging, shock, vibration, etc. The +100 PPB frequency stability has been the most popular as it is sufficient to run microprocessors. The telecommunications industry has been moving toward tighter and tighter frequency stabilities. In order to achieve a better frequency stability and/or compensation of the hardware-related frequency instabilities a filtering method (e.g., an algorithm for controlling the instabilities) is used.

The secondary clock 100 further comprises a control module 106. The control module 106 estimates an offset (e.g., a phase offset) and a skew (e.g., a frequency offset) of the secondary clock 100 based on the reference time and a local time retrieved from the secondary clock 100 (e.g., from the oscillator module 104) for each of the synchronization events.

The offset and the skew of the secondary clock 100 are estimated using a Kalman Filter (KF). The KF comprises an offset variance and a skew variance, wherein the offset variance is indicative of a power of noise of the offset and the skew variance is indicative of a power of noise of the skew. The offset variance is set according to an internal noise power measured for the secondary clock 100 (e.g., white noise and/or random walk) and the skew variance is set according to an external influence (e.g., temperature change) on the secondary clock 100 measured for an environment of the secondary clock 100. The skew variance further is set to a sudden frequency change due to an external environment of the secondary clock 100.

The control module 106 of the secondary clock 100 is further able to update the secondary clock 100 based on the estimated offset and skew. In other words, the control module 106 of the secondary clock 100 is able to correct and/or filter out the instabilities due to the external environment influence on the secondary clock 100, and consequently improves the accuracy of synchronization. The control module 106 is in communication with the receiving module 102 (e.g., for receiving the reference time of the synchronization signals) and the oscillator module 104 (e.g., for retrieving the local time).

Any of the modules of the secondary clock 100 may be implemented by units configured to provide the corresponding functionality.

FIG. 2 shows an example flowchart for a method 200 of synchronizing a secondary clock 100 with a primary clock 300. In a step 202, the secondary clock 100 receives, from the primary clock 300, a synchronization signal indicative of a reference time at each of a plurality of synchronization events. The step 202 may be performed by the receiving module 102.

The plurality of synchronization events may be repeated periodically in a predefined time period (e.g., 1 s, 50 ms to 500 ms, e.g., 100 ms, 500 ms, 250 ms, 125 ms, 62.5 ms, 31.25 ms, etc.). The synchronization signal may be sent in a standard frequency.

In an embodiment, an error bound achieved by the method 200 of synchronizing a secondary clock 100 is linked to both the error inherent in the method 200 itself, and the stability of the frequency of the secondary clock 100. In fact, to some extent, the two are interchangeable. Stable clocks can compensate for a synchronization channel between them that is prone to large (but unbiased) errors since many synchronization events can be averaged over a long time. Similarly, a precise synchronization method 200 can compensate for a poor-stability frequency standard; frequent synchronization minimizes the time in-between when the secondary clock 100 is left to fend for itself.

In a step 204, the secondary clock 100 estimates an offset and a skew of the secondary clock 100 based on the reference time and a local time retrieved from the secondary clock 100 for each of the synchronization events. The local time may be retrieved from the local oscillator module 104 of the secondary clock 100. The step 204 may be performed by the control module 106.

The offset and the skew of the secondary clock 100 are estimated in step 204 using a Kalman filter (KF). The KF comprises an offset variance and a skew variance, wherein the offset variance being indicative of a power of noise of the offset. The noise of the offset may be represented by random walk Gaussian white noise or more divergent noise types, which are sometimes referred to by their color. White noise has a flat spectral density (by analogy to white light).

The offset, θ(Tₙ), represents a difference between the local time, C(Tₙ), retrieved from the secondary clock 100 and the reference time, Tₙ, at the respective synchronization event.

$$θ ( {T}_{n} ) = C ( {T}_{n} ) - {T}_{n}$$

The offset variance may be proportional to the time difference between the synchronization events.

The skew variance is indicative of a power of noise of the skew. The offset variance is set according to an internal noise power measured for the secondary clock 100. The skew variance is set according to an external influence on the secondary clock 100 measured for an environment of the secondary clock 100.

The skew may (e.g., partially) represent a normalized difference, γᵢ, between a frequency, fᵢ, of the second clock 100 and a nominal frequency, f₀, of the second clock 100 at the respective synchronization event.

For example,

$${γ}_{i} = \frac{{f}_{i -} {f}_{0}}{{f}_{0}} .$$

The external influence (e.g., environmental effects) on the secondary clock 100 may cause a sudden and/or relatively large change of the frequency (e.g., 200 PPB to 400 PPB, optionally 300 PPB) of the secondary clock 100. The sudden change in frequency may be a function of time and/or may be approximated with high precision into a first (e.g., linear) or second degree (e.g., parabola) of a polynomial function.

Accordingly, the skew variance may further be quadratic or cubic, respectively, in the time difference between the synchronization events.

The sudden frequency change may be with a good approximation modeled with a linear function, and therefore, the skew variance may be quadratic in the time difference between the synchronization events. The rate of the linear change of the frequency as a function of the time may also be referred to as a slope of the rate ramp.

The KF comprises a covariance matrix. The offset variance,

$${σ}_{θ}^{2} ,$$

and the skew

$${σ}_{γ}^{2} ,$$

multiplied by the synchronization interval may be diagonal elements or eigenvalues of the covariance matrix. Since the skew variance tracks the change of the frequency of the local oscillator, by setting the skew variance according to the measured external influence (e.g., changing the temperature of the secondary clock that leads to the frequency change), the external influence can be compensated.

The method 200 setting the skew variance, related to

$${σ}_{ramp}^{2} ,$$

(i.e., the power of noise of the skew) provides the technical means to filter out the sudden change in frequencies induced by the external influences on the secondary clock 100. The

$${σ}_{ramp}^{2} ,$$

may be a quadratic function of the time difference between the synchronization events. Therefore, with this setting, there is no more need to change the KF to an extended KF (e.g., by using different internal states, wherein state transitions are trigged when detecting the external influence) or changing the time difference between synchronizations (e.g., to a longer or shorter time interval). Hence, embodiments of the method 200 can react to the sudden changes in the frequency very fast and robust as well as filtering out the white noise and random walk of the secondary clock 100.

In a step 206, the method 200 updates the secondary clock 100 based on the estimated 204 offset and skew. Since in the previous step 204 a more precise estimation is introduced, the updating 206 consequently results to a more efficient and accurate synchronization between the primary clock 300 and a secondary clock 100.

The steps 204 and 206 may be performed by the control module 106 of the secondary clock 100.

The method 200 may be performed by the device 100.

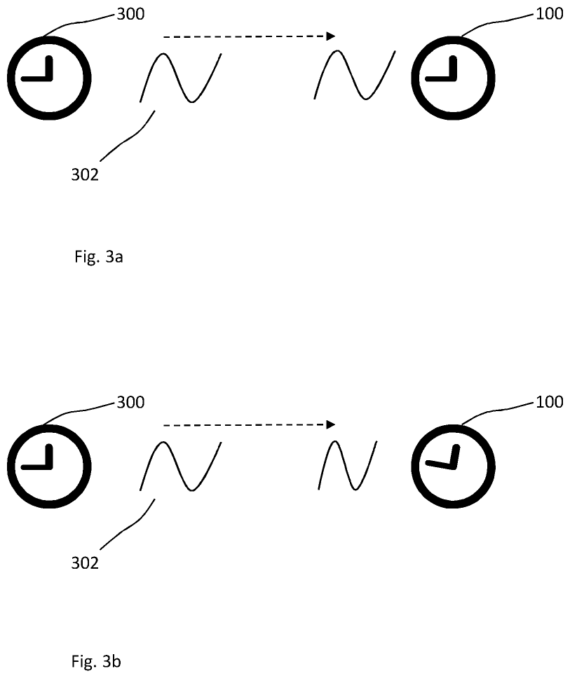

FIG. 3a shows an example of a secondary clock 100 receiving a synchronization signal 302 from a primary clock 300. The primary clock 300 may send the synchronization signals 302 at each of a plurality of synchronization events. The synchronization events may happen periodically in a predefined period.

FIG. 3a shows an exemplary ideal secondary clock 100 in an ideal environmental condition (e.g., constant external influence) receiving a synchronization signal 302 from a primary clock 300 in standard frequency. The frequency generated by the local oscillator 104 of the secondary clock 100 is not changed (e.g., frequency is stable) and therefore the secondary clock 100 synchronized with the primary clock 300.

FIG. 3b shows an exemplary secondary clock 100 in an exemplary real condition (e.g., under the influence of environmental factors) receiving a synchronization signal 302 from a primary clock 300. The frequency generated by the local oscillator 104 of the secondary clock 100 is changed (e.g., frequency is not stable and is influenced by environmental effects) between the synchronization events, therefore the secondary clock 100 is not synchronized with the primary clock 300.

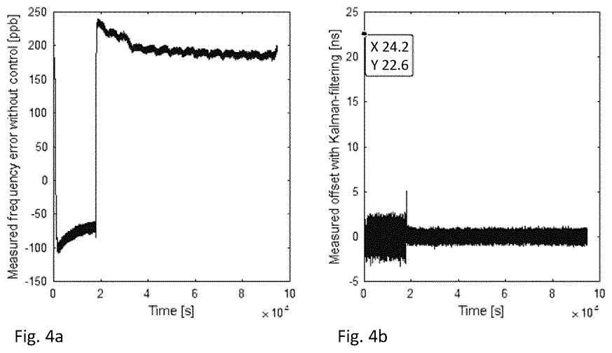

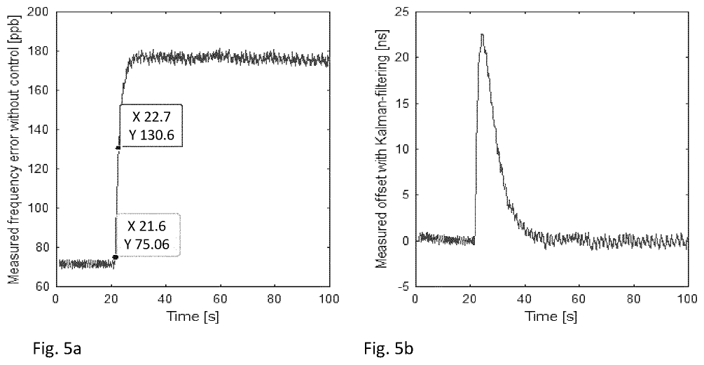

FIG. 4a shows an example effect of an external influence on the frequency of the oscillator 104 in a secondary clock 100 (error in PPB over time in 10ks). In this example, in order to show the effect of temperature change, a cooling fan in vicinity of the secondary clock oscillator 104 is plugged out and plugged in again which causes a sudden change in frequency. The external influence causes a sudden change in oscillator frequency (e.g., a rate ramp, wherein rate refers to the frequency). FIG. 4a shows a measured frequency error. The frequency error drops about 300 PPB during the plugging-out and rises about 330 PPB during the plugging-in.

FIG. 4b shows a reference example of the effect of using a linear KF according to the prior art. A two-state linear KF is applied to filter out stochastic noise sources of known statistical properties (e.g., white frequency noise and/or random walk frequency noise). The covariance matrix of the KF determines the uncertainty of white and random walk frequency noises, respectively:

$$q = ( \begin{matrix}Δ T \cdot {σ}_{θ}^{2} & 0 \\ 0 & Δ T \cdot {σ}_{γ}^{2}\end{matrix} ) .$$

wherein ΔT denotes the synchronization interval, and the deviations de and oy correspond to uncertainty. Herein, γᵢ,

$${γ}_{i} = \frac{{f}_{i} - {f}_{0}}{{f}_{0}} ,$$

is the relative frequency error at the i-th synchronization event (also referred to as synchronization instant, or briefly: instant).

The higher the corresponding variance, the quicker the KF can react on changes due to random walk noise. The random walk noise does not have a considerable effect between two synchronization events. Therefore, a two-state KF was conventionally applied that takes white and random walk noises into consideration. The simulation shows that a maximum error of 24.2 ns would remain in the conventional synchronization method due to the KF, and the error would decrease under 5 ns when no sudden changes occur. In other words, the two-state KF cannot work accurately enough in both normal operation (e.g., when there is no sudden changes) and during a sudden change of frequency.

In order to suppress the effect of rate ramp, the KF may be modified according to the subject technique, e.g., considering the following. The white noise has an observable effect on the secondary clock 100 precision of synchronization between two synchronization events. Contrarily, if synchronization events occur frequently (within 1 s), the effect of random walk noise is undetectable. Therefore, this state variable

$$( {σ}_{γ}^{2} )$$

is modified (i.e., set) to follow the rate ramp.

FIG. 5 shows an example similar to FIG. 4 in a shorter period of time. FIG. 5a shows an exemplary effect of an external influence on the frequency of the oscillator 104 in a secondary clock 100 (error in PPB over time in s). The rate ramp of FIG. 5a can be characterized (e.g., approximated) by the following equation:

$$γ ( t ) = m \cdot t + b ,$$

wherein m is the slope of the ramp and b denotes a bias of the straight line. The resulting frequency error from time instant t₁ to t₂ is:

$$Δ γ ( Δ T ) = γ ( {t}_{2} ) - γ ( {t}_{1} ) = ( m \cdot {t}_{2} + b ) - ( m \cdot {t}_{1} + b ) = m \cdot ( {t}_{2} - {t}_{1} ) = m \cdot Δ T$$

This is a constant value for a given synchronization interval (i.e., time difference between synchronization events). This shows that the rate ramp is not stochastic. The technique may be implemented to compensate for the error by treating the rate ramp as if it was stochastic, e.g., by setting the corresponding deviation, Cramp (or its square value which is the variance).

The KF may expect that the noise (e.g., model errors) has a Gaussian distribution. Following a rate ramp with maximum slope of m, a ramp variance can be set to:

$${σ}_{ramp}^{2} ( Δ T ) = {( \frac{m \cdot Δ T}{3} )}^{2}$$

The reason of this choice is that the maximum change is m·ΔT and for a normally distributed variable, in 99.7% of the cases, the variable is within range ±3σ. Therefore, the standard deviation is m·ΔT/3.

The intention is to replace random walk noise variance with a rate ramp variance (also referred to as variance of the rate ramp). The variance of the random walk noise is (as described for covariance matrix Q of KF):

$${σ}_{γ}^{2} \cdot Δ T \to {σ}_{ramp}^{2} ( Δ T )$$

The random walk variance (e.g., a conventional skew variance) is significantly different from the rate ramp variance as it depends on the synchronization interval linearly, while the rate ramp variance is squarely proportional to the synchronization interval.

From FIG. 5a, the value of m can be read: m=50.49 ppb/s.

As an exemplary comparison, for a KF according to prior art, the standard deviation for the random walk frequency noise was given as 7.7e-11. The resulting random walk variance with 0.1 s synchronization interval is:

$${σ}_{RW}^{2} ( Δ T ) = {σ}_{γ} \cdot Δ T = {( 7.7 \cdot {10}^{- 11} \frac{1}{\sqrt{s}} )}^{2} \cdot 0.1 s = 5.9 \cdot {10}^{- 22}$$

The variance of the rate ramp is:

$${σ}_{ramp}^{2} ( Δ T ) = {( \frac{m \cdot Δ T}{3} )}^{2} = {( \frac{1}{3} \cdot 50.49 \frac{ppb}{s} \cdot 0.1 s )}^{2} = 2.83 \cdot {10}^{- 18}$$

These two equations clearly show why the KF fails to follow the quick frequency change. The two state linear KF assumes that variance is in the range of 1.0e-22, but the real variance (e.g., rate ramp variance) is by 4 order of magnitude higher.

The main idea can be summarized in that the estimation of the random walk is not based on measurements in steady state (when only stochastic processes are significant), but it is estimated during a (worst case) transient, with potentially deterministic drift of the clock signal.

FIG. 5b clearly shows that only applying the two-state KF to suppress the rate ramp is not enough, because it also leads to a high measured offset.

Therefore, a goal of an embodiment of the method 200 is to increase the element of the covariance matrix Q so that the effect of the rate ramp can be suppressed. In other words, the variance related to the random walk frequency change (e.g., the skew variance) is not determined at steady state, where it is negligible between to synchronization instants, but at realistic circumstances, where even or also deterministic effects or the external influence are taken into consideration.

In an embodiment, in order to suppress a steep rate ramp (e.g., corresponding to the external influence), the (standard) deviation (i.e., the square root of the variance) according to the covariance matrix Q used by an embodiment of the method 200 needs to be equal to or greater than the uncertainty injected by the rate ramp noise. For example, to suppress rate ramp noise with slope m, the last element of the covariance matrix Q (e.g., the skew variance) may be set to:

$${Q}_{2 , 2} \geq {σ}_{ramp}^{2} ( Δ T ) = {( \frac{m \cdot Δ T}{3} )}^{2}$$

For instance, to suppress an m=500 ppb/s rate ramp noise, the corresponding parameter setting is:

$${Q}_{2 , 2} \geq {( \frac{500 \frac{ppb}{s} \cdot 0.1 s}{3} )}^{2} = 2.78 \cdot {10}^{- 16}$$

Or equivalently (using KF notation):

$${σ}_{γ}^{2} \geq \frac{{σ}_{ramp}^{2}}{Δ T} = {( \frac{m}{3} )}^{2} \cdot Δ T = {( \frac{500 \frac{ppb}{s}}{3} )}^{2} \cdot 0.1 s = 2.78 \cdot {10}^{- 15} \frac{1}{s} .$$

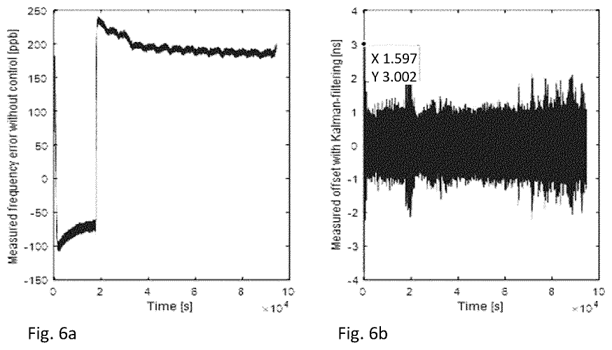

As an example of the usage of the method 200, the KF with the above setting used. The results are depicted in FIG. 6.

FIG. 6 shows that the rate ramp depicted in FIG. 6a is significantly suppressed by using a modified KF according to an embodiment of the method 200, as shown in FIG. 6b. It is noted that the vertical scale is finer compared to FIG. 4b.

The peak at the beginning (in the first moment with 50 PPB/s slop) in FIG. 6a cannot be suppressed using a KF according to the prior art, as is shown in FIGS. 4 and 5. Nevertheless the significantly smaller slops (e.g., no sudden change in frequency) can be suppressed effectively.

In principle, one could argue that the random walk standard deviation of the KF according to prior art, could be increased to infinity in order to suppress the sudden changes in frequency. However, in this case, covariance matrix Q becomes ill-conditioned. The magnitude of the possible increase is determined by the Kalman gain:

$$K ( n ) = {P}_{prior} ( n ) \cdot {( {P}_{prior} ( n ) + R )}^{- 1}$$

The matrix Pₚᵣᵢₒᵣ denotes the covariance of the estimates, which also contains the covariance matrix Q, and R denotes the covariance of the measurement results. If the standard deviation of the random walk noise is increased too much, matrix inversion may become numerically instable. Therefore, numerical considerations should be made (e.g., numerical solution should be considered). Hence, this cannot be a sensible solution.

Another limitation to the increase of the random walk noise parameter (e.g., the skew variance) is that if it is increased too much, only measurement results will be considered for the sudden changes in frequency. In this case, the KF will have quick response time but it will suffer from overshooting problems.

The tuning of the random walk noise parameter (e.g., the setting of the skew variance) according to embodiments of the method 200 enables corresponding embodiments of the device 100 to balance between reaction time and advantageous overshooting properties.

FIG. 6b shows that the modified linear KF according to an embodiment of the method 200 can filter out noise both in steady state and transient state (i.e., during sudden changes in frequency). Therefore, no separate state machine (or separate KF state) is needed, which would involve an extra delay in the control mechanism.

Embodiments of the method 200 realize a suppression of a rate ramp in clock synchronization protocols and/or clock frequency with a linear KF. Although the effect of temperature change on the oscillator frequency error is non-linear, the linear KF structure is adapted so that rate ramp is modeled as a stochastic process.

In order to address the external influences (e.g., a temperature change) on the frequency of the secondary clock (e.g., a local oscillator), the role of a state-variable modeling random walk noise (e.g., the skew variance) is modified. By modifying the skew variance, the robust linear structure of the KF still can be used. The resulting KF is able to filter out slowly changing white and/or random walk frequency noises as well as suddenly frequency changing/rate ramp without the utilization of a separate state machine.

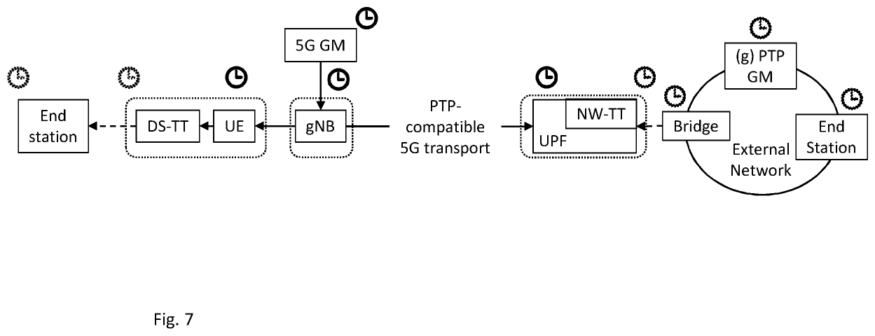

FIG. 7 shows an exemplary usage of the synchronization method 200. FIG. 7 depicts the two exemplary synchronization systems considered: the 5G clock synchronization and the (generalized) peer-to-peer (PTP or gPTP) domain synchronization.
5G Access Stratum Timing Distribution: Used for NG RAN synchronization and also distributed to the UE. 5G Access Stratum timing distribution over the radio interface towards the UE is specified in TS 38.331.
(g)PTP domain synchronization: Provides synchronization service to (g)PTP network. This process follows IEEE Std 802.1AS or IEEE Std 1588-2019.

The two synchronization processes may be considered independent from each other and the gNB (e.g., as the device 100) only needs to be synchronized to the 5G GM clock (e.g., as the primary clock 300). The 5GS may support at least one or each of the following two methods for determining the grandmaster PTP Instance and/or a time-synchronization spanning tree: a first method is a Best Master Clock Algorithm (BMCA) procedure, and a second method is local configuration.

The arrows in FIG. 7 indicate a timing direction. Clocks drawing with thick (or smooth) line are the symbol of the 5GS time synchronization. Clocks drawn with a dashed line are the (g) PTP time synchronization.

Any embodiment of the device 100 may be implemented as a radio device or a base station (e.g., a network node). Herein, any radio device may be a mobile or portable station and/or any radio device wirelessly connectable to a base station or RAN, or to another radio device. For example, the radio device may be a user equipment (UE), a device for machine-type communication (MTC) or a device for (e.g., narrowband) Internet of Things (IoT). Two or more radio devices may be configured to wirelessly connect to each other, e.g., in an ad hoc radio network or via a 3GPP SL connection. Furthermore, any base station may be a station providing radio access, may be part of a radio access network (RAN) and/or may be a node connected to the RAN for controlling the radio access. For example, the base station may be an access point, for example, a Wi-Fi access point.

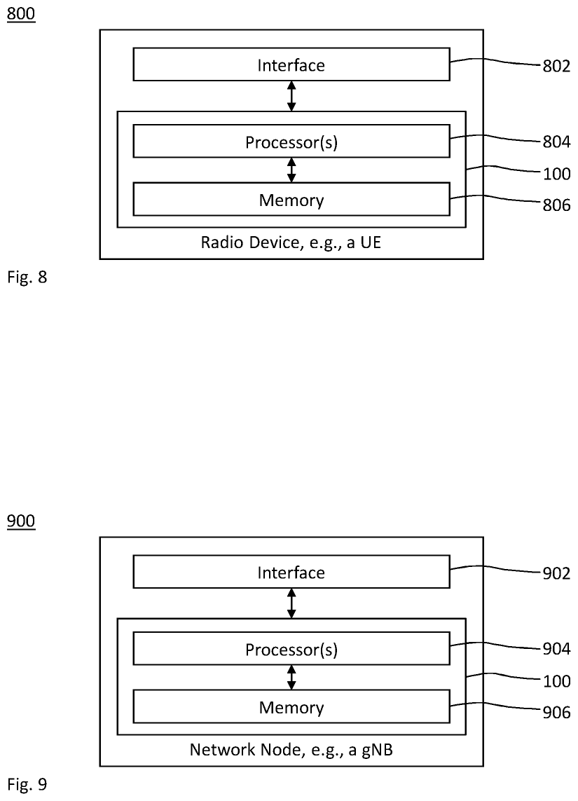

FIG. 8 shows a schematic block diagram for an embodiment of the device 100, which may be combined with any of the above embodiments. The device 100 comprises processing circuitry, e.g., one or more processors 804 for performing the method 300 and memory 806 coupled to the processors 804. For example, the memory 806 may be encoded with instructions that implement at least one of the modules 102, 104 and 106.

The one or more processors 804 may be a combination of one or more of a microprocessor, controller, microcontroller, central processing unit, digital signal processor, application specific integrated circuit, field programmable gate array, or any other suitable computing device, resource, or combination of hardware, microcode and/or encoded logic operable to provide, either alone or in conjunction with other components of the device 100, such as the memory 806, radio device functionality. For example, the one or more processors 804 may execute instructions stored in the memory 806. Such functionality may include providing various features and steps discussed herein, including any of the benefits disclosed herein. The expression “the device being operative to perform an action” may denote the device 100 being configured to perform the action.

As schematically illustrated in FIG. 8, the device 100 may be embodied by a radio device 800, e.g., functioning as a UE. The radio device 800 comprises a radio interface 802 coupled to the device 100 for radio communication with one or more other radio device and/or one or more base station, e.g., functioning as a UE and/or a gNB.

FIG. 9 shows a schematic block diagram for another embodiment of the device 100, which may be combined with any of the above embodiments. The device 100 comprises processing circuitry, e.g., one or more processors 904 for performing the method 400 and memory 906 coupled to the processors 904. For example, the memory 906 may be encoded with instructions that implement at least one of the modules 102, 104 and 106.

The one or more processors 904 may be a combination of one or more of a microprocessor, controller, microcontroller, central processing unit, digital signal processor, application specific integrated circuit, field programmable gate array, or any other suitable computing device, resource, or combination of hardware, microcode and/or encoded logic operable to provide, either alone or in conjunction with other components of the device 100, such as the memory 906, base station functionality. For example, the one or more processors 904 may execute instructions stored in the memory 906. Such functionality may include providing various features and steps discussed herein, including any of the benefits disclosed herein. The expression “the device being operative to perform an action” may denote the device 100 being configured to perform the action.

As schematically illustrated in FIG. 9, the device 100 may be embodied by a network node or base station 900, e.g., functioning as a gNB or eNB. The network node or base station 900 comprises a radio interface 902 coupled to the device 100 for radio communication with one or more radio devices, e.g., functioning as a UE.

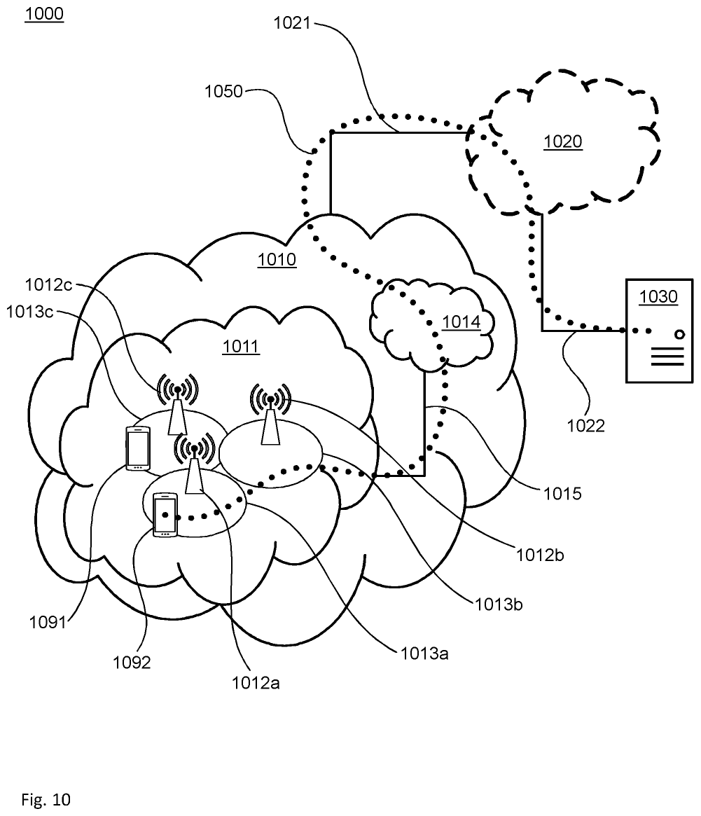

With reference to FIG. 10, in accordance with an embodiment, a communication system 1000 includes a telecommunication network 1010, such as a 3GPP-type cellular network, which comprises an access network 1011, such as a radio access network, and a core network 1014. The access network 1011 comprises a plurality of base stations 1012a, 1012b, 1012c, such as NBs, eNBs, gNBs or other types of wireless access points, each defining a corresponding coverage area 1013a, 1013b, 1013c. Each base station 1012a, 1012b, 1012c is connectable to the core network 1014 over a wired or wireless connection 1015. A piece of first user equipment (UE) 1091 located in coverage area 1013c is configured to wirelessly connect to, or be paged by, the corresponding base station 1012c. A second UE 1092 in coverage area 1013a is wirelessly connectable to the corresponding base station 1012a. While a plurality of UEs 1091, 1092 are illustrated in this example, the disclosed embodiments are equally applicable to a situation where a sole UE is in the coverage area or where a sole UE is connecting to the corresponding base station 1012.

Any of the base stations 1012 and the UEs 1091, 1092 may embody the device 100.

The telecommunication network 1010 is itself connected to a host computer 1030, which may be embodied in the hardware and/or software of a standalone server, a cloud-implemented server, a distributed server or as processing resources in a server farm. The host computer 1030 may be under the ownership or control of a service provider, or may be operated by the service provider or on behalf of the service provider. The connections 1021, 1022 between the telecommunication network 1010 and the host computer 1030 may extend directly from the core network 1014 to the host computer 1030 or may go via an optional intermediate network 1020. The intermediate network 1020 may be one of, or a combination of more than one of, a public, private or hosted network; the intermediate network 1020, if any, may be a backbone network or the Internet; in particular, the intermediate network 1020 may comprise two or more sub-networks (not shown).

The communication system 1000 of FIG. 10 as a whole enables connectivity between one of the connected UEs 1091, 1092 and the host computer 1030. The connectivity may be described as an over-the-top (OTT) connection 1050. The host computer 1030 and the connected UEs 1091, 1092 are configured to communicate data and/or signaling via the OTT connection 1050, using the access network 1011, the core network 1014, any intermediate network 1020 and possible further infrastructure (not shown) as intermediaries. The OTT connection 1050 may be transparent in the sense that the participating communication devices through which the OTT connection 1050 passes are unaware of routing of uplink and downlink communications. For example, a base station 1012 need not be informed about the past routing of an incoming downlink communication with data originating from a host computer 1030 to be forwarded (e.g., handed over) to a connected UE 1091. Similarly, the base station 1012 need not be aware of the future routing of an outgoing uplink communication originating from the UE 1091 towards the host computer 1030.

By virtue of the method 200 being performed by any one of the UEs 1091 or 1092 and/or any one of the base stations 1012, the performance or range of the OTT connection 1050 can be improved, e.g., in terms of increased throughput and/or reduced latency. More specifically, the host computer 1030 may indicate to the primary clock 300 or the device 100 (e.g., on an application layer) the synchronization signal 302.

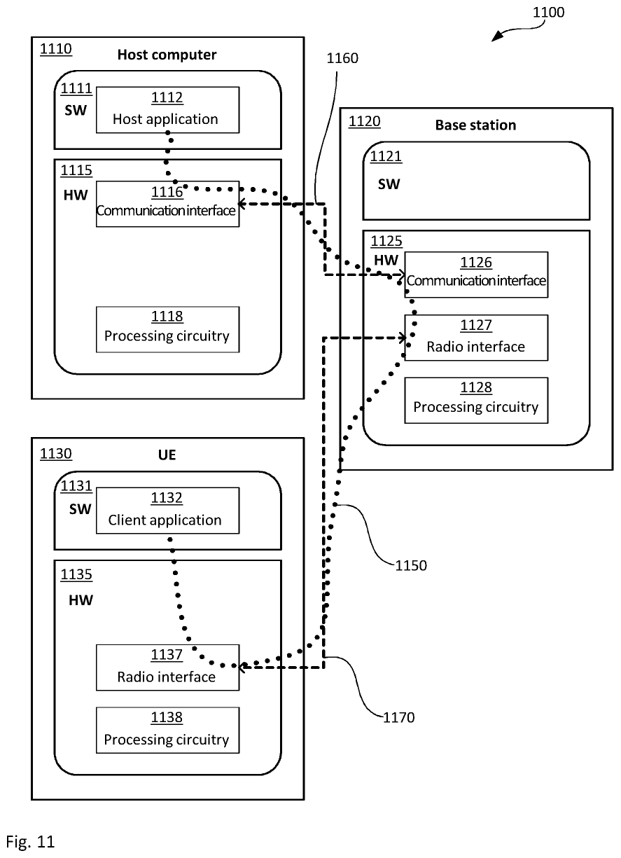

Example implementations, in accordance with an embodiment of the UE, base station and host computer discussed in the preceding paragraphs, will now be described with reference to FIG. 11. In a communication system 1100, a host computer 1110 comprises hardware 1115 including a communication interface 1116 configured to set up and maintain a wired or wireless connection with an interface of a different communication device of the communication system 1100. The host computer 1110 further comprises processing circuitry 1118, which may have storage and/or processing capabilities. In particular, the processing circuitry 1118 may comprise one or more programmable processors, application-specific integrated circuits, field programmable gate arrays or combinations of these (not shown) adapted to execute instructions. The host computer 1110 further comprises software 1111, which is stored in or accessible by the host computer 1110 and executable by the processing circuitry 1118. The software 1111 includes a host application 1112. The host application 1112 may be operable to provide a service to a remote user, such as a UE 1130 connecting via an OTT connection 1150 terminating at the UE 1130 and the host computer 1110. In providing the service to the remote user, the host application 1112 may provide user data, which is transmitted using the OTT connection 1150. The user data may depend on the location of the UE 1130. The user data may comprise auxiliary information or precision advertisements (also: ads) delivered to the UE 1130. The location may be reported by the UE 1130 to the host computer, e.g., using the OTT connection 1150, and/or by the base station 1120, e.g., using a connection 1160.

The communication system 1100 further includes a base station 1120 provided in a telecommunication system and comprising hardware 1125 enabling it to communicate with the host computer 1110 and with the UE 1130. The hardware 1125 may include a communication interface 1126 for setting up and maintaining a wired or wireless connection with an interface of a different communication device of the communication system 1100, as well as a radio interface 1127 for setting up and maintaining at least a wireless connection 1170 with a UE 1130 located in a coverage area (not shown in FIG. 11) served by the base station 1120. The communication interface 1126 may be configured to facilitate a connection 1160 to the host computer 1110. The connection 1160 may be direct, or it may pass through a core network (not shown in FIG. 11) of the telecommunication system and/or through one or more intermediate networks outside the telecommunication system. In the embodiment shown, the hardware 1125 of the base station 1120 further includes processing circuitry 1128, which may comprise one or more programmable processors, application-specific integrated circuits, field programmable gate arrays or combinations of these (not shown) adapted to execute instructions. The base station 1120 further has software 1121 stored internally or accessible via an external connection.

The communication system 1100 further includes the UE 1130 already referred to. Its hardware 1135 may include a radio interface 1137 configured to set up and maintain a wireless connection 1170 with a base station serving a coverage area in which the UE 1130 is currently located. The hardware 1135 of the UE 1130 further includes processing circuitry 1138, which may comprise one or more programmable processors, application-specific integrated circuits, field programmable gate arrays or combinations of these (not shown) adapted to execute instructions. The UE 1130 further comprises software 1131, which is stored in or accessible by the UE 1130 and executable by the processing circuitry 1138. The software 1131 includes a client application 1132. The client application 1132 may be operable to provide a service to a human or non-human user via the UE 1130, with the support of the host computer 1110. In the host computer 1110, an executing host application 1112 may communicate with the executing client application 1132 via the OTT connection 1150 terminating at the UE 1130 and the host computer 1110. In providing the service to the user, the client application 1132 may receive request data from the host application 1112 and provide user data in response to the request data. The OTT connection 1150 may transfer both the request data and the user data. The client application 1132 may interact with the user to generate the user data that it provides.

It is noted that the host computer 1110, base station 1120 and UE 1130 illustrated in FIG. 11 may be identical to the host computer 1030, one of the base stations 1012a, 1012b, 1012c and one of the UEs 1091, 1092 of FIG. 10, respectively. This is to say, the inner workings of these entities may be as shown in FIG. 11, and, independently, the surrounding network topology may be that of FIG. 10.

In FIG. 11, the OTT connection 1150 has been drawn abstractly to illustrate the communication between the host computer 1110 and the UE 1130 via the base station 1120, without explicit reference to any intermediary devices and the precise routing of messages via these devices. Network infrastructure may determine the routing, which it may be configured to hide from the UE 1130 or from the service provider operating the host computer 1110, or both. While the OTT connection 1150 is active, the network infrastructure may further take decisions by which it dynamically changes the routing (e.g., on the basis of load balancing consideration or reconfiguration of the network).

The wireless connection 1170 between the UE 1130 and the base station 1120 is in accordance with the teachings of the embodiments described throughout this disclosure. One or more of the various embodiments improve the performance of OTT services provided to the UE 1130 using the OTT connection 1150, in which the wireless connection 1170 forms the last segment. More precisely, the teachings of these embodiments may reduce the latency and improve the data rate and thereby provide benefits such as better responsiveness and improved QoS.

A measurement procedure may be provided for the purpose of monitoring data rate, latency, QoS and other factors on which the one or more embodiments improve. There may further be an optional network functionality for reconfiguring the OTT connection 1150 between the host computer 1110 and UE 1130, in response to variations in the measurement results. The measurement procedure and/or the network functionality for reconfiguring the OTT connection 1150 may be implemented in the software 1111 of the host computer 1110 or in the software 1131 of the UE 1130, or both. In embodiments, sensors (not shown) may be deployed in or in association with communication devices through which the OTT connection 1150 passes; the sensors may participate in the measurement procedure by supplying values of the monitored quantities exemplified above, or supplying values of other physical quantities from which software 1111, 1131 may compute or estimate the monitored quantities. The reconfiguring of the OTT connection 1150 may include message format, retransmission settings, preferred routing etc.; the reconfiguring need not affect the base station 1120, and it may be unknown or imperceptible to the base station 1120. Such procedures and functionalities may be known and practiced in the art. In certain embodiments, measurements may involve proprietary UE signaling facilitating the host computers 1110 measurements of throughput, propagation times, latency and the like. The measurements may be implemented in that the software 1111, 1131 causes messages to be transmitted, in particular empty or “dummy” messages, using the OTT connection 1150 while it monitors propagation times, errors etc.

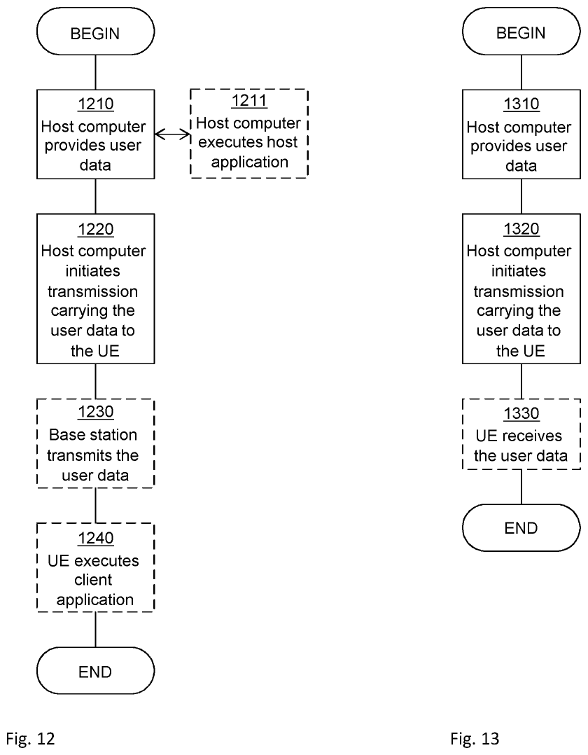

FIG. 12 is a flowchart illustrating a method implemented in a communication system, in accordance with one embodiment. The communication system includes a host computer, a base station and a UE which may be those described with reference to FIGS. 10 and 11. For simplicity of the present disclosure, only drawing references to FIG. 12 will be included in this paragraph. In a first step 1210 of the method, the host computer provides user data. In an optional substep 1211 of the first step 1210, the host computer provides the user data by executing a host application. In a second step 1220, the host computer initiates a transmission carrying the user data to the UE. In an optional third step 1230, the base station transmits to the UE the user data which was carried in the transmission that the host computer initiated, in accordance with the teachings of the embodiments described throughout this disclosure. In an optional fourth step 1240, the UE executes a client application associated with the host application executed by the host computer.

FIG. 13 is a flowchart illustrating a method implemented in a communication system, in accordance with one embodiment. The communication system includes a host computer, a base station and a UE which may be those described with reference to FIGS. 10 and 11. For simplicity of the present disclosure, only drawing references to FIG. 13 will be included in this paragraph. In a first step 1310 of the method, the host computer provides user data. In an optional substep (not shown) the host computer provides the user data by executing a host application. In a second step 1320, the host computer initiates a transmission carrying the user data to the UE. The transmission may pass via the base station, in accordance with the teachings of the embodiments described throughout this disclosure. In an optional third step 1330, the UE receives the user data carried in the transmission.

As has become apparent from above description, at least some embodiments of the technique allow for an improved synchronization between a secondary clock and a primary clock.

Although the rate ramp may be deterministic, embodiments may implement or model it as a stochastic process that can be handled by a linear KF. Therefore, no nonlinear extension is needed, keeping the algorithm simple and robust.

In same or further embodiments, the resulting KF may be able to follow sudden changes due to the random walk state variable (e.g., the skew variance), and small perturbations due to the white noise component (e.g., the offset variance).

Preferably, no separate state machine is needed to determine whether the system is in steady state or in transient state (e.g., under the external influence).

The method 200 may be implemented as an improvement over an existing two-state linear KF to make it responsive to rate ramp, besides slowly varying random walk and white noise. Embodiments may make use of small synchronization intervals (10⁻¹-10⁰ s) and compress random walk and white noise information into one single state variable.

Any embodiment may alter or replace or release the role of a random walk noise parameter (a skew variance). For example, the skew variance may be set to (e.g., may be parametrized with) an increased uncertainty to be able to react on a rate ramp. The high uncertainty in the parameter will have an effect that measured results will be dominant over modeled values. By this means, a fast response time is achieved, e.g., by following measured data. On the other hand, a slowly varying random walk and/or white frequency noises are suppressed based on a combination of the model (e.g., the offset variance set according to method 200) and measurement results retrieved in each synchronization event for a linear KF.

Alternatively or in addition, embodiments of the method 200 can achieve at least one of the following benefits (e.g., compared to existing techniques):
Improved robustness: unlike existing KF implementations, which use extended, nonlinear KF solutions, to handle the ramp rate in the local oscillator 104, this disclosure may propose using a linear KF, that is much more favorable due to its robustness; and
Quick response to changes of the local oscillator 104: Same or further embodiments eliminate the need for complex additions to KFs (such as an external state machines or adaptive extensions like Sage-Husa Kalman filtering) to detect and react on changes in the synchronization behavior due to a ramp rate change in the local oscillator 104, therefore providing quick response and high accuracy.

Many advantages of the present invention will be fully understood from the foregoing description, and it will be apparent that various changes may be made in the form, construction and arrangement of the units and devices without departing from the scope of the invention and/or without sacrificing all of its advantages. Since the invention can be varied in many ways, it will be recognized that the invention should be limited only by the scope of the following claims.

1.-35. (canceled)

36. A method of synchronizing a secondary clock with a primary clock, the method comprising:
receiving, from the primary clock, a synchronization signal indicative of a reference time at each of a plurality of synchronization events; and
estimating an offset and a skew of the secondary clock based on the reference time and a local time retrieved from the secondary clock for each of the synchronization events, wherein the offset and the skew of the secondary clock are estimated using a Kalman filter (KF) comprising an offset variance and a skew variance, the offset variance being indicative of a power of noise of the offset and the skew variance being indicative of a power of noise of the skew, wherein the offset variance is set according to an internal noise power measured for the secondary clock and wherein the skew variance is set according to an external influence on the secondary clock measured for an environment of the secondary clock; and
updating the secondary clock based on the estimated offset and skew.

37. The method of claim 36, wherein the offset represents a difference between the local time retrieved from the secondary clock and the reference time at the respective synchronization event.

38. The method of claim 36, wherein the skew represents a normalized difference between a frequency of the secondary clock and a nominal frequency of the secondary clock at the respective synchronization event.

39. The method of claim 38, wherein a change in the environment causes the skew of the secondary clock and the skew of the frequency of the local oscillator.

40. The method of claim 36, wherein the secondary clock comprises a local oscillator, wherein the frequency of the secondary clock is the frequency of the local oscillator and/or the nominal frequency of the secondary clock is the nominal frequency of the local oscillator.

41. The method of claim 36, wherein the synchronization events occur periodically.

42. The method of claim 36, wherein a time or time difference between the synchronization events is less than 1 second.

43. The method of claim 36, wherein the offset variance is proportional to a time difference between the synchronization events and/or wherein the skew variance is quadratic in the time difference between the synchronization events.

44. The method of claim 36, wherein the skew variance is set to the square value of an upper bound of the change in frequency caused by the external influence on the secondary clock during the time between the synchronization events.

45. The method of claim 36, wherein the offset variance is configured to track the change of the offset during the time between the synchronizations and/or during a time interval in a range of 0.1 seconds to 1 second.

46. The method of claim 36, wherein the external influence causes, or is represented by, a linear change of the frequency of the secondary clock as a function of time.

47. The method of claim 36, wherein the skew variance is proportional to the square value of a rate of a linear change of the frequency or is proportional to the square value of the linear change of the frequency.

48. The method of claim 36, wherein the external influence is a change in the environment of the secondary clock.

49. The method of claim 36, wherein the secondary clock is thermally coupled to a heat sink, and wherein the external influence comprises at least one of:
a failure of a heat pump coupling the heat sink and the local oscillator;
a failure of a ventilator at the heat sink;
an exposure of the heat sink to sun light depending on solar altitude;
an increase in the temperature of the local oscillator; and
a decrease in the temperature of the local oscillator.

50. The method of claim 36, wherein the KF does not comprise a multi-state machine for detecting the external influence.

51. The method of claim 36, wherein the skew variance comprises a dimensionless coefficient.

52. The method of claim 36, wherein the skew variance is increased if a maximum of a measured offset between the local time and the reference time over a measurement interval is greater than a predefined time error limit, wherein the measurement interval is greater than the time between the synchronization events.

53. A device for synchronizing a secondary clock with a primary clock, the device comprising:
a radio interface; and
processing circuitry configured to:
receive, from the primary clock, a synchronization signal indicative of a reference time at each of a plurality of synchronization events; and
estimate an offset and a skew of the secondary clock based on the reference time and a local time retrieved from the secondary clock for each of the synchronization events, wherein the offset and the skew of the secondary clock are estimated using a Kalman filter (KF) comprising an offset variance and a skew variance, the offset variance being indicative of a power of noise of the offset and the skew variance being indicative of a power of noise of the skew, wherein the offset variance is set according to an internal noise power measured for the secondary clock and wherein the skew variance is set according to an external influence on the secondary clock measured for an environment of the secondary clock; and
update the secondary clock based on the estimated offset and skew.

54. The device of claim 53, wherein the device is a user equipment (UE) configured to communicate with a base station or with a radio device functioning as a gateway.

55. The device of claim 53, wherein the device is a network node in a communication network.
